(19) United States
(12) Patent Application Publication
(10) Pub. No.: US 2026/0251678 A1
(43) Pub. Date: Aug. 27, 2026

(54) PROBE HAVING LOW BALANCE CONTACT FORCE

(71) Applicant: XINGR TECHNOLOGIES (ZHEJIANG) LIMITED, YIWU CITY (CN)

(72) Inventors: CHOON LEONG LOU, SINGAPORE (SG); HO YEH CHEN, HSINCHU COUNTY (TW)

(21) Appl. No.: 19/292,869

(22) Filed: Aug. 6, 2025

(30) Foreign Application Priority Data
Feb. 27, 2025 (CN) 202510222775.1

(51) Int. Cl. G01R 1/067

(52) U.S. Cl. CPC G01R 1/06716; G01R 1/0675

(57) ABSTRACT

A probe having a low balance contact force includes an elastic structure and an electrical conductor. The elastic structure has a first surface and a second surface, and the first surface and the second surface are arranged on opposite sides of the elastic structure. The electrical conductor includes a first electrical conductor and a second electrical conductor. The first surface of the elastic structure corresponds to the first electrical conductor, the second surface of the elastic structure corresponds to the second electrical conductor, and the first electrical conductor and the second electrical conductor are tightly combined and cover the elastic structure.

### FIELD OF THE DISCLOSURE

The present disclosure relates to a probe structure, and more particularly to a probe with a lower balance force.

### BACKGROUND OF THE DISCLOSURE

Electrical testing is required for the manufacturing process of integrated circuit chips. The integrated circuit chip is usually provided with pads or bumps of the electrode part, and the test probe is electrically connected to the electrode part to measure the electrical properties of the chip. When the probe comes into contact with the electrode part, the tip of the probe applies needle pressure/balance contact force (BCF) to the electrode part to make an electrical connection.

If the probe comes into contact with the electrode part with too much needle pressure, a deep or elongated scratch mark will be formed on the electrode part, which affects the strength of chip soldering in the subsequent process. Therefore, the pressure with which the probe contacts the electrode part has to be well controlled. In conventional technology, the body of the probe can include two parallel pillars with at least one opening therebetween, and the parallel pillars and the opening serve as an elastic structure to reduce the needle pressure of the probe in contact with the electrode part.

The two parallel pillars provided in the probe are prone to breakage. In conventional technology, the opening can be filled with a polymeric material as a support to increase the strength, thereby reducing the risk of pillar breakage. However, the needle pressure of the probe on the electrode part increases, which is not only detrimental to the test, but also cannot solve the problem of increased impedance.

Further, during high current testing or high frequency testing, it is desirable to control the needle pressure as well as reduce the impedance of the probe itself. In terms of probes with the same cross-sectional area and the same material, although the needle pressure is reduced in conventional technology by configuring the opening, the impedance increases, which is unfavorable to the requirements for high current testing or high frequency testing, and the risk of probe breakage has not been resolved. Existing solutions may, for example, increase the cross-sectional area of the probe by increasing the thickness of the probe, but an increase in the cross-sectional area of the probe is accompanied by an increase of the needle pressure. Therefore, there is a need for a probe in which the needle pressure as well as the impedance can be reduced and the breakage can be prevented, to overcome the above issues, thereby providing more efficient testing for high frequency and electrical micromachines.

### SUMMARY OF THE DISCLOSURE

It is an object of the present disclosure to provide a probe having a low balance contact force, which includes an elastic structure and an electrical conductor. The elastic structure has a first surface of elastic structure and a second surface of elastic structure, and the first surface of elastic structure and the second surface of elastic structure are arranged on opposite sides of the elastic structure. The electrical conductor includes a first electrical conductor and a second electrical conductor. The first surface of elastic structure corresponds to the first electrical conductor, the second surface of elastic structure corresponds to the second electrical conductor, and the first electrical conductor and the second electrical conductor are tightly combined and cover at least a portion of the elastic structure. A hardness of the elastic structure is greater than a hardness of the electrical conductor.

In one of the possible or preferred embodiments, a plurality of ribs includes a first rib and a second rib, and the connecting section has a first area in a cross-section perpendicular to a central line of the elastic structure and exposed between the first rib and the second rib. The first rib has a first rib cross-section, the second rib has a second rib cross-section, the first rib cross-section has a side edge of first rib cross-section, the second rib cross-section has a side edge of second rib cross-section, and the side edge of first rib cross-section and the side edge of second rib cross-section are adjacent to and face each other. The electrical conductor has a top surface of electrical conductor and a bottom surface of electrical conductor, the top surface of electrical conductor and the bottom surface of electrical conductor are opposite surfaces of the electrical conductor, the top surface of electrical conductor has one side edge of top surface of electrical conductor and another side edge of top surface of electrical conductor that are parallel to each other, the one side edge of top surface of electrical conductor is adjacent to the side edge of first rib cross-section, and the another side edge of top surface of electrical conductor is adjacent to the side edge of second rib cross-section. A second area is defined by a distance of the side edge of first rib cross-section extending perpendicularly to the one side edge of top surface of electrical conductor and the side edge of first rib cross-section, and a third area is defined by a distance of the side edge of second rib cross-section extending perpendicularly to the another side edge of top surface of electrical conductor and the side edge of second rib cross-section.

In one of the possible or preferred embodiments, a fourth area is defined by a distance of the one side edge of top surface of electrical conductor extending to the another side edge of top surface of electrical conductor and the side edge of first rib cross-section.

In one of the possible or preferred embodiments, the elastic structure further has a top surface of elastic structure and a bottom surface of elastic structure, the top surface of elastic structure and the bottom surface of elastic structure are arranged at opposite ends of the elastic structure with respect to the central line. The first surface of elastic structure is corresponding connected to the top surface of elastic structure and the bottom surface of elastic structure, and the second surface of elastic structure is correspondingly connected to the top surface of elastic structure and the bottom surface of elastic structure. When the top surface of elastic structure is aligned with the top surface of electrical conductor and the bottom surface of elastic structure is aligned with the bottom surface of electrical conductor, the top surface of elastic structure and the bottom surface of elastic structure are not covered by the electrical conductor.

In one of the possible or preferred embodiments, when the top surface of elastic structure is provided in engagement with the top surface of electrical conductor, and the bottom surface of elastic structure is provided in engagement with the bottom surface of electrical conductor, the top surface of elastic structure and the bottom surface of elastic structure are covered by the electrical conductor.

In one of the possible or preferred embodiments, at least a portion of the electrical conductor is arranged in a space.

In one of the possible or preferred embodiments, a material of the elastic structure is a nickel alloy, a nickel-cobalt alloy, platinum, or a platinum alloy.

In one of the possible or preferred embodiments, a material of each of the first electrical conductor and the second electrical conductor is a material with high electrical conductivity, such as gold, silver, and copper.

In one of the possible or preferred embodiments, the first electrical conductor and the second electrical conductor are stacked on the elastic structure by electroplating.

In one of the possible or preferred embodiments, the first electrical conductor and the second electrical conductor are tightly combined by fusion.

In one of the possible or preferred embodiments, a material of the first electrical conductor and a material of the second electrical conductor are the same.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of an elastic structure of a probe having a low balance contact force according to a first embodiment of the present disclosure;

FIG. 2 is schematic view of the probe having the low balance contact force according to the first embodiment of the present disclosure;

FIG. 3 is a schematic front view of the probe having the low balance contact force according to the first embodiment of the present disclosure;

FIG. 4 is a schematic cross-sectional view taken along line IV-IV of FIG. 2;

FIG. 5 is a schematic view of an elastic structure of a probe having a low balance contact force according to a second embodiment of the present disclosure;

FIG. 6 is a schematic view of the probe having the low balance contact force according to the second embodiment of the present disclosure; and

FIG. 7 is another schematic view of the probe having the low balance contact force according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

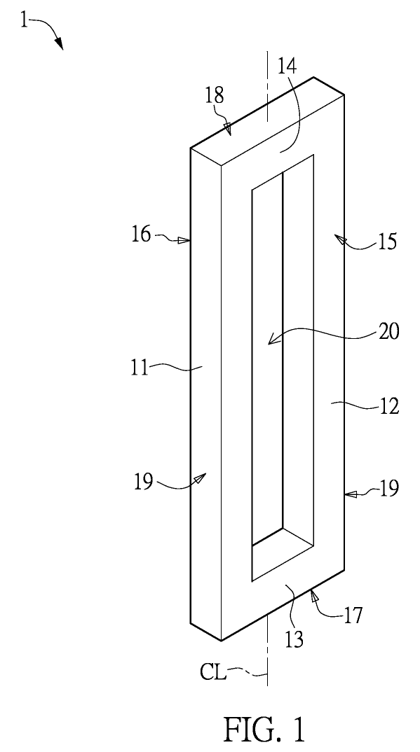

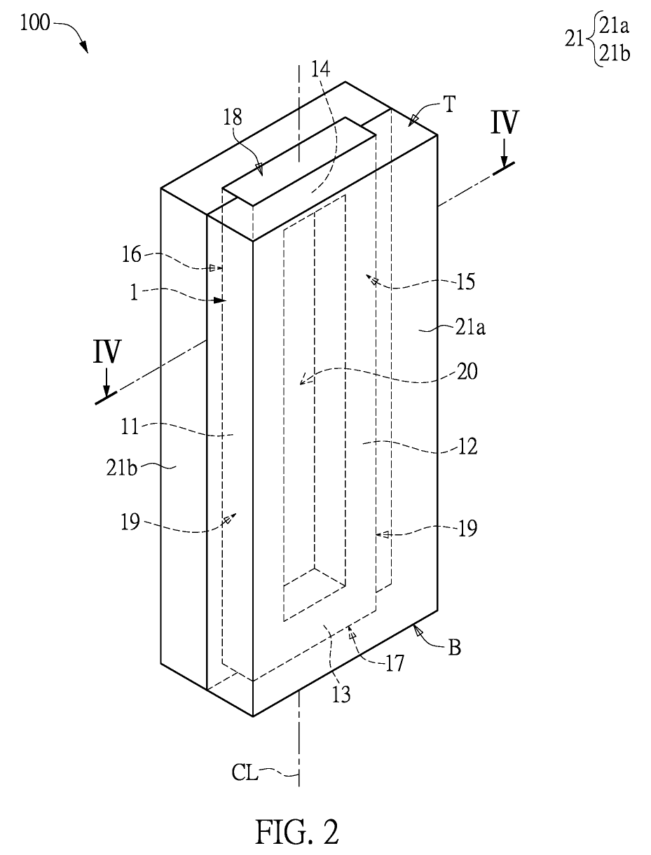

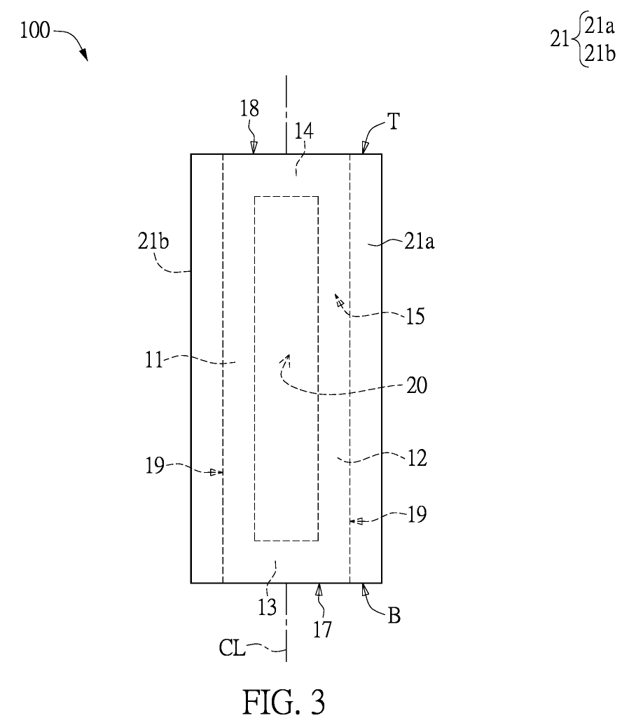

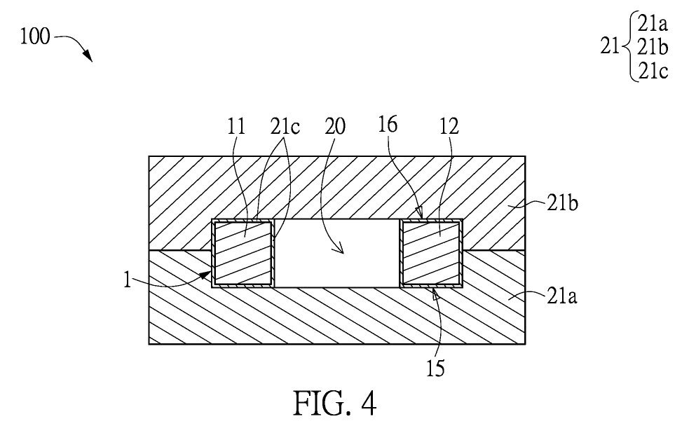

Referring to FIGS. 1 to 4, FIG. 1 is a schematic view of an elastic structure 1 of a probe having a low balance contact force 100 according to a first embodiment of the present disclosure, FIG. 2 is schematic view of the probe having the low balance contact force 100 according to the first embodiment of the present disclosure, FIG. 3 is a schematic front view of the probe having the low balance contact force 100 according to the first embodiment of the present disclosure, and FIG. 4 is a schematic cross-sectional view taken along line IV-IV of FIG. 2.

The present disclosure provides the probe having the low balance contact force 100, which includes the elastic structure 1 and an electrical conductor 21. The elastic structure 1 is a probe which can be a single probe, can be of various shapes (e.g., an S-shaped probe), or can be a micro electro mechanical systems (MEMS) pogo pin probe structure, but the present disclosure is not limited thereto.

Referring to FIG. 1, in the first embodiment of the present disclosure, the elastic structure 1 of the probe having the low balance contact force 100 includes two ribs (i.e., a first rib 11 and a second rib 12) and two connecting sections (i.e., a first connecting section 13 and a second connecting section 14). The first connecting section 13 is correspondingly connected to one corresponding end of the first rib 11 and one corresponding end of the second rib 12, and the second connecting section 14 is correspondingly connected to another corresponding end of the first rib 11 and another corresponding end of the second rib 12. A space 20 is defined between the first rib 11 and the second rib 12. It should be noted that the present disclosure does not limit a number of each of the ribs, the connecting sections, and the space 20. The ribs can be provided with two, three, or more than four. The connecting sections can be provided with two, three, or more than four. The number of the space 20 is determined according to the number of the ribs, and can be more than one.

The elastic structure 1 has a first surface of elastic structure 15 and a second surface of elastic structure 16. The first surface of elastic structure 15 and the second surface of elastic structure 16 are arranged on opposite sides of the elastic structure 1. The elastic structure 1 also has a bottom surface of elastic structure 17 and a top surface of elastic structure 18, and the bottom surface of elastic structure 17 and the top surface of elastic structure 18 are arranged at opposite ends of the elastic structure 1 with respect to a central line CL. The bottom surface of elastic structure 17 can be a surface of the first connecting section 13 away from the second connecting section 14, and the top surface of elastic structure 18 can be a surface of the second connecting section 14 away from the first connecting section 13. The first surface of elastic structure 15 is corresponding connected to the top surface of elastic structure 18 and the bottom surface of elastic structure 17, and the second surface of elastic structure 16 is correspondingly connected to the top surface of elastic structure 18 and the bottom surface of elastic structure 17. The elastic structure 1 also has two side surfaces of elastic structure 19. Each of the two side surfaces of elastic structure 19 is correspondingly connected to the first surface of elastic structure 15, the second surface of elastic structure 16, the bottom surface of elastic structure 17, and the top surface of elastic structure 18.

Referring to FIG. 2, the probe having the low balance contact force 100 includes the electrical conductor 21, including a first electrical conductor 21a and a second electrical conductor 21b. The first surface of elastic structure 15 corresponds to the first electrical conductor 21a, and the second surface of elastic structure 16 corresponds to the second electrical conductor 21b. In one embodiment, the first electrical conductor 21a and the second electrical conductor 21b can be formed on the elastic structure 1 by electroplating. In one embodiment, the first electrical conductor 21a and the second electrical conductor 21b can be two individual components, which are tightly combined by high pressure and/or high temperature fusion and cover the elastic structure 1.

At least a portion of the first electrical conductor 21a and/or at least a portion of the second electrical conductor 21b can be arranged in the space 20. Specifically, the space 20 is also covered with a plating layer due to the electroplating, so that at least the portion of the first electrical conductor 21a is arranged in a portion of the space 20 or at least the portion of the first electrical conductor 21a is arranged in all of the space 20, and at least the portion of the second electrical conductor 21b is arranged in the portion of the space 20 or at least the portion of the second electrical conductor 21b is arranged in all of the space 20. Specifically, when the fusion method is adopted, at least the portion of the first electrical conductor 21a is arranged in a portion of the space 20 or at least the portion of the first electrical conductor 21a is arranged in all of the space 20, and at least the portion of the second electrical conductor 21b is arranged in the portion of the space 20 or at least the portion of the second electrical conductor 21b is arranged in all of the space 20. That is, the space 20 can be filled with the first electrical conductor 21a or the second electrical conductor 21b, or can be not filled with the first electrical conductor 21a or the second electrical conductor 21b.

Referring to FIGS. 2 and 3, the electrical conductor 21 has a bottom surface of electrical conductor B and a top surface of electrical conductor T. When the first electrical conductor 21a and the second electrical conductor 21b cover the elastic structure 1 to be tightly combined, the bottom surface of elastic structure 17 can be aligned with the bottom surface of electrical conductor B, and the top surface of elastic structure 18 can be aligned with the top surface of electrical conductor T. In addition, the two side surfaces of elastic structure 19 of the elastic structure 1 are covered by the electrical conductor 21. When the top surface of elastic structure 18 is aligned with the top surface of electrical conductor T and the bottom surface of elastic structure 17 is aligned with the bottom surface of electrical conductor B, the top surface of elastic structure 18 and the bottom surface of elastic structure 17 are not covered by the electrical conductor 21. That is, the bottom surface of elastic structure 17 is coplanar with the bottom surface of electrical conductor B, and the top surface of elastic structure 18 is coplanar with the top surface of electrical conductor T. However, the present disclosure is not limited thereto. Specifically, in one embodiment, when the top surface of elastic structure 18 is provided in engagement with the top surface of electrical conductor T, and the bottom surface of elastic structure 17 is provided in engagement with the bottom surface of electrical conductor B, the bottom surface of elastic structure 17 and the top surface of elastic structure 18 can be covered by the electrical conductor 21, through which a test is not affected. However, after several tests, the bottom surface of elastic structure 17 and the top surface of elastic structure 18 are usually exposed and not covered by the electrical conductor 21.

Referring to FIG. 4, FIG. 4 is the schematic cross-sectional view taken along line IV-IV of FIG. 2. As can be seen in FIG. 4, the electrical conductor 21 can be partially formed on the elastic structure 1 by electroplating to form a third electrical conductor 21c as shown in FIG. 4. Then, the first electrical conductor 21a and the second electrical conductor 21b are tightly combined by high pressure and/or high temperature fusion to cover the elastic structure 1 provided with third electrical conductor 21c. Optionally, at least the portion of the first electrical conductor 21a and/or at least the portion of the second electrical conductor 21b can be arranged in the space 20, but the present disclosure is not limited thereto. Optionally, in the present embodiment, the third electrical conductor 21c, which is tightly coupled to and covers the elastic structure 1, can also constitute the entire electrical conductor 21.

Optionally, a material of the elastic structure 1 can be a nickel alloy, a nickel-cobalt alloy, platinum, or a platinum alloy.

Optionally, the elastic structure 1 can be an electrical conductor, and an electrical conductivity of each of the first electrical conductor 21a and the second electrical conductor 21b can be greater than an electrical conductivity of the elastic structure 1.

Optionally, a material of each of the first electrical conductor 21a and the second electrical conductor 21b can be a material with high electrical conductivity, such as gold, silver, and copper.

Optionally, the material of the first electrical conductor 21a and the material of the second electrical conductor 21b can be the same material, so that the first electrical conductor 21a and the second electrical conductor 21b can be selectively and stably fused, or the electroplating process is easier to implement.

Optionally, a hardness of the elastic structure 1 is greater than a hardness of the electrical conductor 21. Specifically, the elastic structure 1 with the higher hardness covered by the electrical conductor 21 serves as a support, such that a needle pressure generated when the elastic structure 1 is in contact with an object to be tested can be not excessively increased, and impedance can be reduced.

Through the configuration of the electrical conductor 21 of the present disclosure, a current path of the probe having the low balance contact force 100 can be overall increased, thereby reducing the impedance. However, if the first electrical conductor 21a and the second electrical conductor 21b are made of a material with the same hardness as the elastic structure 1, or with the hardness greater than the hardness of the elastic structure 1, the needle pressure is significantly increased, resulting in excessive contact pressure on the object to be tested, thereby affecting subsequent testing and processing of a chip.

Optionally, after the first electrical conductor 21a and the second electrical conductor 21b are fused by high pressure and/or high temperature, a cross-section of the probe (i.e., probe size) can be adjusted by laser, CNC processing, or etching. If the material around the probe having the low balance contact force 100 that has undergone the fusion has irregular projections, an appearance of the probe can be smoothened by the above method.

### Second Embodiment

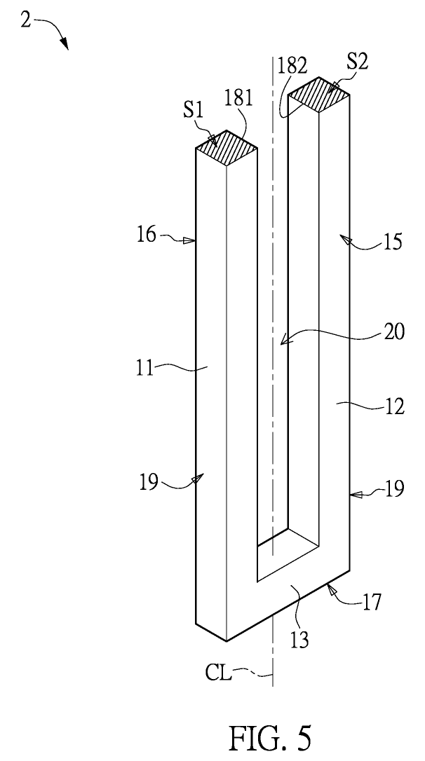

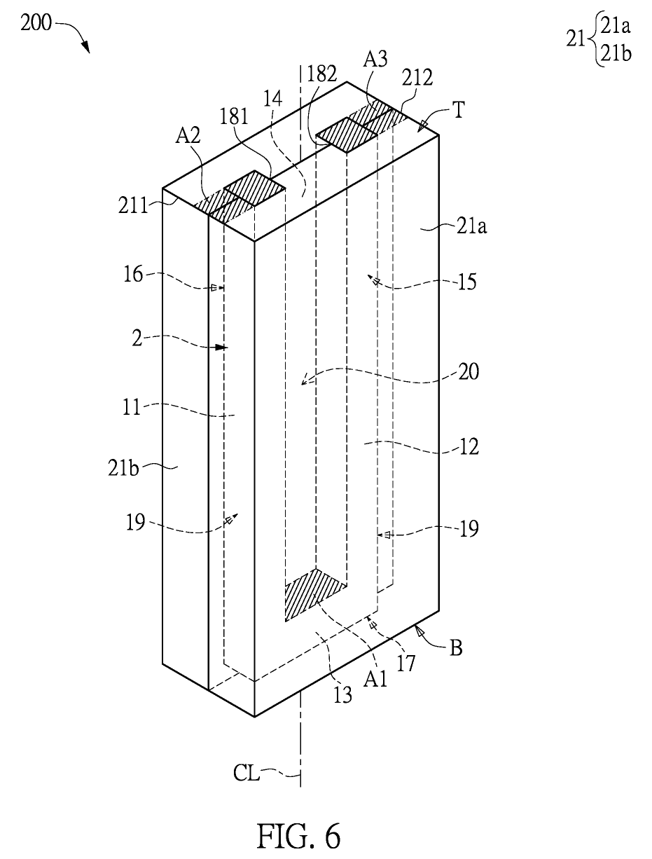

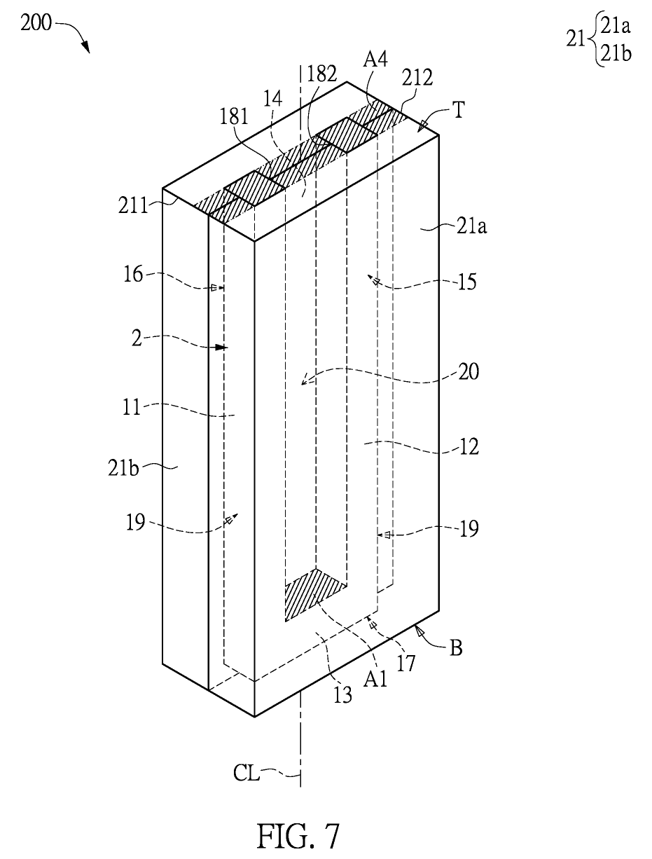

Referring to FIGS. 5 to 7, FIG. 5 is a schematic view of an elastic structure 2 of a probe having a low balance contact force 200 according to a second embodiment of the present disclosure, FIG. 6 is a schematic view of the probe having the low balance contact force 200 according to the second embodiment of the present disclosure, and FIG. 7 is another schematic view of the probe having the low balance contact force 200 according to the second embodiment of the present disclosure. A configuration of the second embodiment of the present disclosure is similar to that of the first embodiment, and the similarities will not be reiterated herein. The second embodiment of the present disclosure is different from the first embodiment in that, in the second embodiment, only one connecting section is provided in the elastic structure 2 and correspondingly connected to the first rib 11 and the second rib 12. According to an actual implementation, the elastic structure 2 of the second embodiment can include only one connecting section (i.e., the first connecting section 13) correspondingly connected to one corresponding end of the first rib 11 and one corresponding end of the second rib 12, and another end of the first rib 11 and another end of the second rib 12 are left unconnected, so that the first rib 11, the second rib 12, and the first connecting section 13 collectively constitute the elastic structure 2 similar to a concave shape or a U shape.

Referring to FIG. 5, in the second embodiment, the first rib 11 of the elastic structure 2 has a first rib cross-section S1, and the second rib 12 of the elastic structure 2 has a second rib cross-section S2. The first rib cross-section S1 has a side edge of first rib cross-section 181, and the second rib cross-section S2 has a side edge of second rib cross-section 182. The bottom surface of elastic structure 17 and a surface of the first connecting section 13 away from the first rib cross-section S1 and the second rib cross-section S2.

Referring to FIG. 6, the first connecting section 13 has a first area A1 in a cross-section perpendicular to the central line CL. The side edge of first rib cross-section 181 and the side edge of second rib cross-section 182 are adjacent to and face each other. The top surface of electrical conductor T has one side edge of top surface of electrical conductor 211 and another side edge of top surface of electrical conductor 212 that are parallel to each other, the one side edge of top surface of electrical conductor 211 is adjacent to the side edge of first rib cross-section 181, and the another side edge of top surface of electrical conductor 212 is adjacent to the side edge of second rib cross-section 182. An area defined by a distance of the side edge of first rib cross-section 181 extending perpendicularly to the one side edge of top surface of electrical conductor 211 and the side edge of first rib cross-section 181 is a second area A2, and an area defined by a distance of the side edge of second rib cross-section 182 extending perpendicularly to the another side edge of top surface of electrical conductor 212 and the side edge of second rib cross-section 182 is a third area A3. A sum of the second area A2 and the third area A3 is greater than or equal to the first area A1.

Optionally, reference is made to FIG. 7, in which another schematic view of the probe having the low balance contact force 200 according to the second embodiment of the present disclosure is shown, wherein a fourth area A4 is defined by a distance of the one side edge of top surface of electrical conductor 211 extending to the another side edge of top surface of electrical conductor 212 and the side edge of first rib cross-section 181. The fourth area A4 is greater than the first area A1.

Similarly, the electrical conductor 21 has the bottom surface of electrical conductor B and the top surface of electrical conductor T. When the first electrical conductor 21a and the second electrical conductor 21b cover the elastic structure 1 to be tightly combined, the first rib cross-section S1 of the first rib 11 and the second rib cross-section S2 of the second rib 12 are correspondingly aligned with the top surface of electrical conductor T. That is, the first rib cross-section S1 and the second rib cross-section S2 are correspondingly coplanar with the top surface of electrical conductor T and are not covered by the electrical conductor 21. When a cross-section of the bottom surface of elastic structure 17 perpendicular to the central line CL is aligned with the bottom surface of electrical conductor B, i.e., the top surface of electrical conductor T is coplanar with the bottom surface of electrical conductor B, the bottom surface of elastic structure 17 is not covered by the electrical conductor 21. Similarly, the two side surfaces of elastic structure 19 of the elastic structure 2 are covered by the electrical conductor 21. Similarly, in one embodiment, when the top surface of elastic structure 18 is provided in engagement with the top surface of electrical conductor T, and the bottom surface of elastic structure 17 is provided in engagement with the bottom surface of electrical conductor B, the bottom surface of elastic structure 17 and the top surface of elastic structure 18 can be covered by the electrical conductor 21, through which the test is not affected. However, after several tests, the bottom surface of elastic structure 17 and the top surface of elastic structure 18 are usually exposed and not covered by the electrical conductor 21.

### Beneficial Effects of the Embodiments

One of the beneficial effects of the present disclosure is that in the probe having the low balance contact force provided in the present disclosure, by virtue of covering the elastic structure with the greater hardness by the electrical conductor with the less hardness, the current path of the probe having the low balance contact force can be overall increased, thereby reducing the impedance. In addition, a risk of the probe breaking when contacting the object to be tested can be effectively reduced, resulting in a more effective test process. Another beneficial effect of the present disclosure is that by arranging a plurality of ribs adjacent to each other, the space can be defined between two adjacent ribs so as to achieve the control of the needle pressure, so that the scratching of an electrode part on the object to be tested can be reduced, thereby avoiding the subsequent chip soldering process being affected.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A probe having a low balance contact force, comprising:
an elastic structure having a first surface of elastic structure and a second surface of elastic structure, the first surface of elastic structure and the second surface of elastic structure being arranged on opposite sides of the elastic structure, the elastic structure including:
a plurality of ribs; and
at least one connecting section correspondingly connected to two ribs that are adjacent to each other;
wherein the two ribs that are adjacent to each other and the at least one connecting section collectively define at least one space; and
an electrical conductor including a first electrical conductor and a second electrical conductor;
wherein the first surface of elastic structure of the elastic structure corresponds to the first electrical conductor, the second surface of elastic structure of the elastic structure corresponds to the second electrical conductor, and the first electrical conductor and the second electrical conductor are tightly combined and cover at least a portion of the elastic structure;
wherein a hardness of the elastic structure is greater than a hardness of the electrical conductor.

2. The probe having the low balance contact force according to claim 1, wherein the plurality of ribs includes a first rib and a second rib, and the connecting section has a first area in a cross-section perpendicular to a central line of the elastic structure and exposed between the first rib and the second rib;
wherein the first rib has a first rib cross-section, the second rib has a second rib cross-section, the first rib cross-section has a side edge of first rib cross-section, the second rib cross-section has a side edge of second rib cross-section, and the side edge of first rib cross-section and the side edge of second rib cross-section are adjacent to and face each other;
wherein the electrical conductor has a top surface of electrical conductor and a bottom surface of electrical conductor, the top surface of electrical conductor and the bottom surface of electrical conductor are opposite surfaces of the electrical conductor, the top surface of electrical conductor has one side edge of top surface of electrical conductor and another side edge of top surface of electrical conductor that are parallel to each other, the one side edge of top surface of electrical conductor is adjacent to the side edge of first rib cross-section, and the another side edge of top surface of electrical conductor is adjacent to the side edge of second rib cross-section;
wherein a second area is defined by a distance of the side edge of first rib cross-section extending perpendicularly to the one side edge of top surface of electrical conductor and the side edge of first rib cross-section, a third area is defined by a distance of the side edge of second rib cross-section extending perpendicularly to the another side edge of top surface of electrical conductor and the side edge of second rib cross-section, and a sum of the second area and the third area is greater than or equal to the first area.

3. The probe having the low balance contact force according to claim 2, wherein a fourth area is defined by a distance of the one side edge of top surface of electrical conductor extending to the another side edge of top surface of electrical conductor and the side edge of first rib cross-section; and
wherein the fourth area is greater than the first area.

4. The probe having the low balance contact force according to claim 2, wherein the elastic structure further has a top surface of elastic structure and a bottom surface of elastic structure, the top surface of elastic structure and the bottom surface of elastic structure are arranged at opposite ends of the elastic structure with respect to a central line, the first surface of elastic structure is corresponding connected to the top surface of elastic structure and the bottom surface of elastic structure, and the second surface of elastic structure is correspondingly connected to the top surface of elastic structure and the bottom surface of elastic structure;
wherein, when the top surface of elastic structure is aligned with the top surface of electrical conductor and the bottom surface of elastic structure is aligned with the bottom surface of electrical conductor, the top surface of elastic structure and the bottom surface of elastic structure are not covered by the electrical conductor.

5. The probe having the low balance contact force according to claim 2, wherein the elastic structure further has a top surface of elastic structure and a bottom surface of elastic structure, the top surface of elastic structure and the bottom surface of elastic structure are arranged at opposite ends of the elastic structure with respect to a central line; the first surface of elastic structure is corresponding connected to the top surface of elastic structure and the bottom surface of elastic structure, and the second surface of elastic structure is correspondingly connected to the top surface of elastic structure and the bottom surface of elastic structure;
wherein, when the top surface of elastic structure is provided in engagement with the top surface of electrical conductor, and the bottom surface of elastic structure is provided in engagement with the bottom surface of electrical conductor, the top surface of elastic structure and the bottom surface of elastic structure are covered by the electrical conductor.

6. The probe having the low balance contact force according to claim 5, wherein at least a portion of the electrical conductor is arranged in the space.

7. The probe having the low balance contact force according to claim 1, wherein a material of the elastic structure is a nickel alloy, a nickel-cobalt alloy, platinum, or a platinum alloy.

8. The probe having the low balance contact force according to claim 1, wherein a material of each of the first electrical conductor and the second electrical conductor is a material with high electrical conductivity, such as gold, silver, and copper.

9. The probe having the low balance contact force according to claim 1, wherein the first electrical conductor and the second electrical conductor are stacked on the elastic structure by electroplating.

10. The probe having the low balance contact force according to claim 1, wherein the first electrical conductor and the second electrical conductor are tightly combined by fusion.

11. The probe having the low balance contact force according to claim 1, wherein a material of the first electrical conductor and a material of the second electrical conductor are the same.
